(19) United States
(12) Patent Application Publication
(10) Pub. No.: US 2026/0140194 A1
(43) Pub. Date: May 21, 2026

(54) METHOD AND APPARATUS FOR PROTECTING A BATTERY

(71) Applicants: HYUNDAI MOTOR COMPANY, Seoul (KR); KIA CORPORATION, Seoul (KR)

(72) Inventor: Seung Won Kang, Hwaseong-si (KR)

(73) Assignees: HYUNDAI MOTOR COMPANY, Seoul (KR); KIA CORPORATION, Seoul (KR)

(21) Appl. No.: 19/225,629

(22) Filed: Jun. 2, 2025

(30) Foreign Application Priority Data
Nov. 21, 2024 (KR) 10-2024-0167097

(51) Int. Cl. G01R 31/392; G01R 31/36; G01R 31/388

(52) U.S. Cl. CPC G01R 31/392; G01R 31/3648; G01R 31/388

(57) ABSTRACT

A method and apparatus for protecting a battery includes or performs monitoring a state of a vehicle; determining an estimated SOC; determining an SOC at which a current starts to decrease by charging a battery at a constant voltage, as a reference SOC; and predicting an SOH by comparing an absolute value of a difference between the estimated SOC and the reference SOC with a preset numerical value.

### CROSS-REFERENCE TO RELATED APPLICATION

This application claims the benefit of and priority to Korean Patent Application No. 10-2024-0167097, filed on Nov. 21, 2024, the entire disclosure of which is hereby incorporated herein by reference in its entirety.

### TECHNICAL FIELD

The present disclosure relates to a method and an apparatus for protecting a battery. More specifically, the present disclosure relates to a method and an apparatus for protecting durability of a battery.

### BACKGROUND

The content described below merely provides background information relating to the present disclosure, and does not constitute the related art.

In the related art, a State Of Health (SOH) of a battery may be predicted by internal resistance of the battery, a driving distance of a vehicle, and the like. However, in order to predict the SOH of the battery, these methods require additional processes such as parameter extraction. Therefore, there is a demand for a simplified technique capable of predicting the SOH by estimating a State of Charge (SOC).

In addition, the above-described methods do not adopt a separate control method to delay an aging progress of the battery. Therefore, there is a demand for a technique capable of controlling the battery to improve a lifespan of the battery by using a result of predicting the SOH.

### SUMMARY

The present disclosure provides a method and an apparatus for protecting durability of a battery by estimating a State of Charge (SOC), predicting a State of Health (SOH), and setting an available area.

Aspects to be achieved by the present disclosure are not limited to the aspects described herein, and other aspects not described herein should be clearly understood by those having ordinary skill in the art from the description below.

According to an embodiment, a battery protection method includes: determining an estimated SOC; determining an SOC at which a current starts to decrease by charging a battery at a constant voltage, as a reference SOC; and predicting an SOH by comparing an absolute value of a difference between the estimated SOC and the reference SOC with a preset numerical value.

According to another embodiment, an apparatus includes: at least one memory storing instructions; and at least one processor. The at least one processor, by executing the instructions, is configured to determine an estimated SOC, determine an SOC at which a current starts to decrease by charging the battery at a constant voltage, as a reference SOC and predict the SOH by comparing an absolute value of a difference between the estimated SOC and the reference SOC with a preset numerical value.

According to one embodiment of the present disclosure, there is an advantageous effect of protecting durability of a battery by estimating a SOC, predicting a SOH, and setting an available area.

The advantageous effects of the present disclosure are not limited to the advantageous effects described herein, and other advantageous effects not described herein should be clearly understood by those having ordinary skill in the art from the description below.

### BRIEF DESCRIPTION OF THE DRAWINGS

FIG. 1 is a block diagram schematically illustrating a battery protection apparatus according to one embodiment of the present disclosure.

FIG. 2 is a diagram for describing a reference SOC depending on a battery SOH according to an embodiment of the present disclosure.

FIG. 3 is a diagram illustrating a process in which the battery protection apparatus according to one embodiment of the present disclosure estimates the battery SOH.

FIG. 4 is a diagram illustrating a process in which the battery protection apparatus according to one embodiment of the present disclosure sets a battery available area.

FIG. 5 is a flowchart illustrating a battery protection method according to one embodiment of the present disclosure.

FIG. 6 is a block diagram schematically illustrating an example computing device which may be used to implement a method according to the present disclosure.

### DETAILED DESCRIPTION

Hereinafter, embodiments of the present disclosure are described in detail with reference to the accompanying drawings. In the following description, like reference numerals designate like elements, although the elements are shown in different drawings. Further, in the following description of some embodiments, a detailed description of known functions and configurations incorporated therein has been omitted for the purpose of clarity and for brevity.

Additionally, various terms such as first, second, A, B, (a), (b), and the like, are used solely to differentiate one component from the other but not to imply or suggest the substances, order, or sequence of the components. Throughout the present disclosure, when a part ‘includes’ or ‘comprises’ a component, the part is intended to further include other components and not intended to exclude other components unless specifically stated to the contrary. The terms such as ‘unit’, ‘module’, and the like refer to one or more units for processing at least one function or operation, which may be implemented by hardware, software, or a combination thereof. When a processor, controller, module, component, device, element, or the like of the present disclosure is described as having a purpose or performing an operation, function, or the like, the processor, controller, module, component, device, element, or the like should be considered herein as being “configured to” meet that purpose or to perform that operation or function. Each controller, unit, module, component, device, element, and the like may separately embody or be included with a processor and a memory, such as a non-transitory computer readable media, as part of the apparatus. In the present disclosure, each of phrases such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases.

The following detailed description, together with the accompanying drawings, is intended to illustrate embodiments of the present disclosure and is not intended to represent the only embodiments in which the disclosure may be practiced.

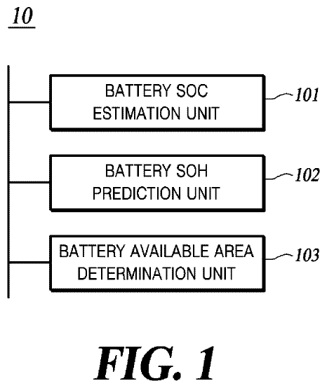

FIG. 1 is a block diagram schematically illustrating a battery protection apparatus according to one embodiment of the present disclosure.

As illustrated in FIG. 1, a battery protection apparatus (10) according to one embodiment of the present disclosure may include all or some of a battery SOC estimation unit (101), a battery SOH prediction unit (102), and a battery available area setting/determination unit (103). All blocks illustrated in FIG. 1 are not essential components, and some blocks included in the battery protection apparatus (10) in other embodiments may be added, changed, or deleted. The components illustrated in FIG. 1 represent functionally distinct elements, and may be implemented in a form in which at least one or more components are integrated with each other in an actual physical environment.

The battery SOC estimation unit (101) may determine an estimated SOC by using an SOC estimation method. The SOC estimation method includes a current integration method, an Open Circuit Voltage (OCV) measurement method, a chemical measurement method, and/or a pressure measurement method.

The battery SOC estimation unit (101) may determine the estimated SOC by using a current integration method. The battery SOC estimation unit (101) may determine the estimated SOC by integrating input and output currents of the battery and adding or subtracting an integration result to or from initial capacity.

The battery SOC estimation unit (101) may determine the estimated SOC of the battery by using an OCV measurement method. The OCV measurement method is a method for measuring a voltage in a state where no load is connected to the battery.

The battery SOC estimation unit (101) may determine the estimated SOC through the chemical measurement method by measuring a specific gravity or acidity (pH) of a battery electrolyte.

The battery SOC estimation unit (101) may determine the estimated SOC through the pressure measurement method by measuring an internal pressure of the battery.

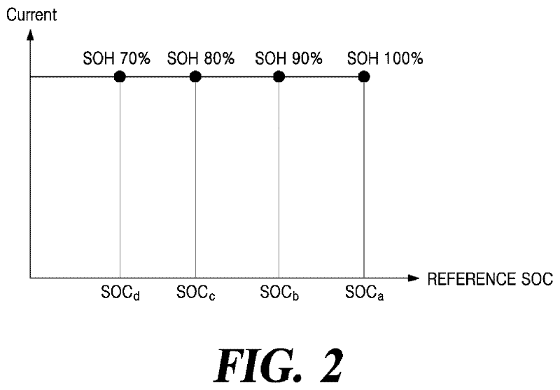

FIG. 2 is a diagram for describing a reference SOC depending on a battery SOH according to an embodiment of the present disclosure.

The battery SOH prediction unit (102) may determine the reference SOC. The reference SOC is the SOC at which a current starts to decrease when the battery is charged by using a Constant Current Constant Voltage (CCCV). The battery SOH prediction unit (102) may determine the SOC at which the current starts to decrease by charging the battery at a constant voltage by using the CCCV, as the reference SOC.

The battery SOH prediction unit (102) may generate an SOC map through a battery characteristic test. Referring to FIG. 2, even when the battery is charged with a Constant Current (CC) having the same size and a Constant Voltage (CV) having the same size, a difference may occur in the reference SOC, depending on the battery SOH. The SOC map is data that predicts the SOH for each reference SOC. For example, referring to the SOC map in Table 1, when the reference SOC is SOCa, it is predicted that the SOH is 100%, when the reference SOC is SOCb, it is predicted that the SOH is 90%, when the reference SOC is SOCc, it is predicted that the SOH is 80%, and when the reference SOC is SOCd, it is predicted that the SOH is 70%.

TABLE 1

Reference SOC

| | SOCa | SOCb | SOCc | SOCd |
|---|---|---|---|---|
| SOH Prediction Value | 100% | 90% | 80% | 70% |

The battery SOH prediction unit (102) may predict the battery SOH by using the reference SOC and the estimated SOC. The battery SOH prediction unit (102) may predict the SOH through the SOH map by using the reference SOC when an absolute value of a difference between the estimated SOC and the reference SOC exceeds a preset numerical value.

The battery available area setting unit (103) may set the battery available area in accordance with the battery SOH. The battery available area setting unit (103) may set the battery available area by setting an SOC lower limit value (which may also be referred to as an SOC minimum value) and an SOC upper limit value (which may also be referred to as an SOC maximum value). The battery available area setting unit (103) may set the battery available area by fixing the SOC minimum value and changing the SOC maximum value. For example, the battery available area setting unit (103) may fix the SOC minimum value to 10% and set the SOC maximum value to 90% to set the available area to 80%. The battery available area setting unit (103) may fix the SOC minimum value to 10% and change the SOC maximum value to 50% to change the available area to 40%.

Referring to Table 2, as the SOC maximum value is smaller, a lifespan cycle increases. The battery available area setting unit (103) may increase a lifespan of the battery, and may protect durability of the battery by fixing the SOC minimum value and changing the maximum value. The battery available area setting unit (103) may increase the lifespan of the battery, and may protect the durability of the battery by fixing the SOC minimum value and preventing over-discharge.

TABLE 2

| Depth of Discharge | Battery Available Area | Lifespan Cycle |
|---|---|---|
| 75% | 25% to 100% | 3500 |
| 60% | 40% to 100% | 4500 |
| 50% | 50% to 100% | 5500 |
| 60% | 25% to 80% | >5200 |
| 50% | 25% to 75% | >5500 |

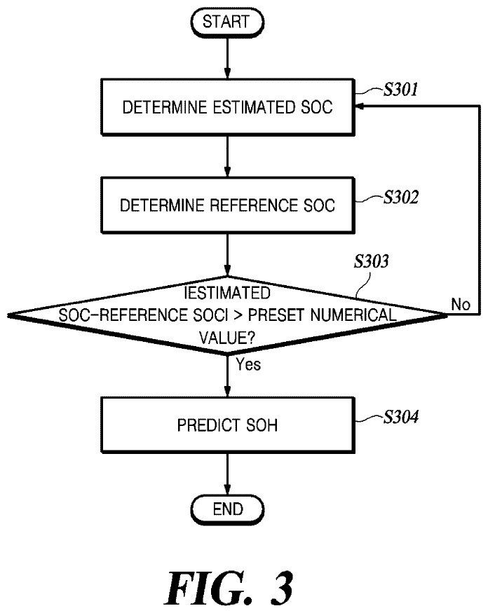

FIG. 3 is a diagram illustrating a process in which the battery protection apparatus according to one embodiment of the present disclosure estimates the battery SOH.

The battery protection apparatus (10) may determine the estimated SOC by using the SOC estimation method (S301). The SOC estimation method includes a current integration method, an OCV measurement method, a chemical measurement method, and/or a pressure measurement method.

The battery protection apparatus (10) may determine the reference SOC (S302). The battery protection apparatus (10) may charge the battery at a constant voltage by using the CCCV, and may determine the SOC at which the current starts to decrease, as the reference SOC.

The battery protection apparatus (10) compares an absolute value of a difference between the reference SOC and the estimated SOC with a preset numerical value (S303).

When the absolute value of the difference between the reference SOC and the estimated SOC is equal to or smaller than the preset numerical value (“No” at S303), the battery protection apparatus (10) determines the estimated SOC by using the SOC estimation method (S301).

When the absolute value of the difference between the reference SOC and the estimated SOC exceeds the preset numerical value (“Yes” at S303), the battery protection apparatus (10) predicts the SOH through the SOH map by using the reference SOC (S304). The battery protection apparatus (10) may receive an input of the SOC map from the outside, or the battery protection apparatus may generate the SOC map through a battery characteristic test.

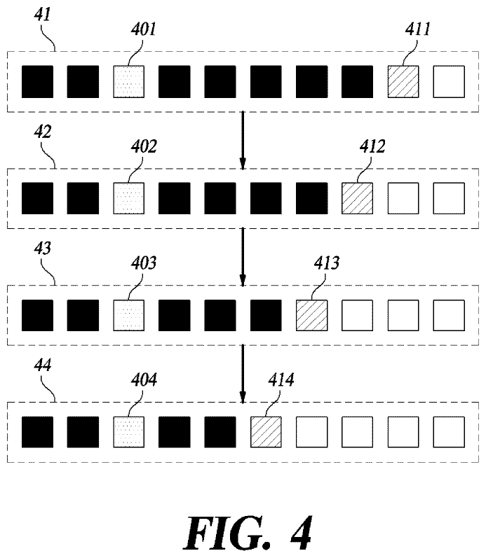

FIG. 4 is a diagram illustrating a process in which the battery protection apparatus according to one embodiment of the present disclosure sets the battery available area.

The battery protection apparatus (10) may set the battery available area, based on an SOH prediction result. The battery protection apparatus (10) may set the battery available area by setting the SOC minimum value and the SOC maximum value. The battery protection apparatus (10) may set the battery available area by fixing the SOC minimum values (401, 402, 403, and 404) and changing the SOC maximum values (411, 412, 413, and 414). The battery protection apparatus (10) may decrease the SOC maximum value as much as the SOH decreases.

For example, when the battery SOH is 90% (41), the battery protection apparatus (10) may set the available area to 90% by determining the minimum SOC (401) and the maximum SOC (411). When the battery SOH decreases to 80% (42), the battery protection apparatus (10) may set the available area to 80% by decreasing the maximum SOC (412) as much as the SOH decreases without changing the minimum SOC (402). When the battery SOH decreases to 70% (43), the battery protection apparatus (10) may set the available area to 70% by decreasing the maximum SOC (413) as much as the SOH decreases without changing the minimum SOC (403). When the battery SOH decreases to 60% (44), the battery protection apparatus (10) may set the available area to 60% by decreasing the maximum SOC (404) as much as the SOH decreases without changing the minimum SOC (414).

The battery protection apparatus may predict the SOH without extracting battery characteristic parameters depending on the SOH. The battery protection apparatus may simplify implementation of an SOH prediction algorithm. The battery protection apparatus may improve the lifespan of the battery by decreasing the available area in accordance with an aging state of the battery. The battery protection apparatus may further improve the lifespan of the battery by decreasing the SOC maximum value in accordance with the aging state of the battery. The battery protection apparatus may also minimize the battery capacity by controlling the battery to increase the amount of electric energy which can be used by the battery during a warranty period.

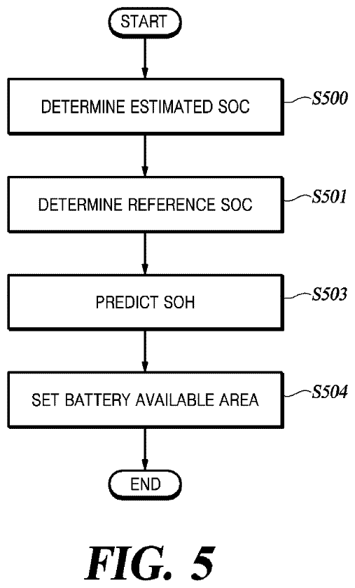

FIG. 5 is a flow chart illustrating a battery protection method according to one embodiment of the present disclosure. The method illustrated in FIG. 5 may be implemented by being executed by a battery protection system implemented with one or more physical devices including the battery protection apparatus (10) in FIG. 1. The following operations are described in terms of operations performed by the battery protection system.

The battery protection system may determine the estimated SOC by using the SOC estimation method (S500). The SOC estimation method includes a current integration method, an OCV measurement method, a chemical measurement method, and/or a pressure measurement method.

The battery protection system may determine the estimated SOC through the current integration method by integrating the input and output currents of the battery and adding or subtracting the integration result to or from the initial capacity.

The battery protection system is provided, based on the OCV measurement method by measuring the voltage in a state where no load is connected to the battery.

The battery protection system may determine the estimated SOC through the chemical measurement method by measuring the specific gravity or the acidity (pH) of the battery electrolyte.

The battery protection system may determine the estimated SOC through the pressure measurement method by measuring the internal pressure of the battery.

The battery protection system may charge the battery at a constant voltage by using the CCCV, and may determine the SOC at which the current starts to decrease, as the reference SOC (S501).

The battery protection system may predict the SOH by using the reference SOC and the estimated SOC (S503). The battery protection system compares the absolute value of the difference between the reference SOC and the estimated SOC with the preset numerical value. When the absolute value of the difference between the reference SOC and the estimated SOC is equal to or greater than the preset numerical value, the battery protection system predicts the SOH through the SOH map by using the reference SOC.

The battery protection system may set the battery available area by using the SOH prediction result and setting the SOC minimum value and the SOC maximum value (S504). The battery protection system may set the battery available area by fixing the SOC minimum value and changing the SOC maximum value. For example, when the SOH prediction result shows that the SOH decreases, the battery protection system may decrease the battery available area by decreasing the SOH maximum value as much as the SOH decreases without changing the SOC minimum value.

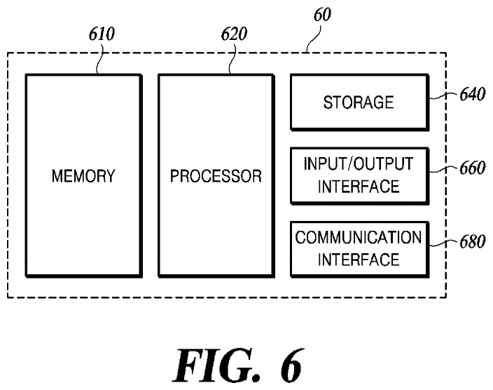

FIG. 6 is a block diagram schematically illustrating an example computing device which may be used to implement a method according to the present disclosure.

A computing device (60) may include some or all of a memory (610), a processor (620), a storage (640), an input/output interface (660), and a communication interface (680). The computing device (60) may structurally and/or functionally include at least a portion of the battery protection apparatus (10). The computing device (60) may be not only a stationary computing device such as a desktop computer, a server, and an AI (Artificial Intelligence) accelerator, but also a portable computing device such as a laptop computer and a smart phone.

The memory (610) may store a program that causes the processor (620) to perform a method or an operation according to various embodiments of the present disclosure. For example, the program may include a plurality of commands executable by the processor (620), and the above-described method may be performed by the processor (620) executing the plurality of commands.

The memory (610) may be a single memory or a plurality of memories. In this case, information required for performing the method or the operation according to various embodiments of the present disclosure may be stored in a single memory, or may be divided and stored in the plurality of memories. When the memory (610) includes the plurality of memories, the plurality of memories may be physically separated. The memory (910) may be physically separated.

The memory (610) may include at least one of a volatile memory and a nonvolatile memory. The volatile memory includes a Static Random Access Memory (SRAM) or a Dynamic Random Access Memory (DRAM), and the nonvolatile memory includes a flash memory.

The processor (620) may include at least one core capable of executing at least one instruction. The processor (620) may execute commands stored in the memory (610). The processor (620) may be a single processor or a plurality of processors.

The storage (640) maintains stored data even when power supplied to the computing device (60) is cut off. For example, the storage (640) may include the nonvolatile memory, or may include storage media such as a magnetic tape, an optical disk, and a magnetic disk.

The program stored in the storage (640) may be loaded into the memory (610) before being executed by the processor (620). The storage (640) may store a file written in a programming language, and the program generated from the file by a compiler or the like may be loaded into the memory (610). The storage (640) may store data to be processed by the processor (620) and/or data processed by the processor (620).

The input/output interface (660) may include an input device such as a keyboard and a mouse, and may include an output device such as a display device and a printer. The user may trigger the processor (620) to execute the program and/or may check a processing result of the processor (620) through the input/output interface.

The communication interface (680) may provide access to an external network. For example, the computing device (60) may communicate with other devices via the communication interface (680).

Each element of the apparatus or method in accordance with the present disclosure may be implemented in hardware, software, or a combination of hardware and software. The functions of the respective elements may be implemented in software, and a microprocessor may be implemented to execute the software functions corresponding to the respective elements.

Various embodiments of systems and techniques described herein can be realized with digital electronic circuits, integrated circuits, field programmable gate arrays (FPGAs), application specific integrated circuits (ASICs), computer hardware, firmware, software, and/or combinations thereof. The various embodiments can include implementation with one or more computer programs that are executable on a programmable system. The programmable system includes at least one programmable processor, which may be a special purpose processor or a general purpose processor, coupled to receive and transmit data and instructions from and to a storage system, at least one input device, and at least one output device. Computer programs (also known as programs, software, software applications, or code) include instructions for a programmable processor and are stored in a “computer-readable recording medium.”

A computer-readable storage medium includes any type of recording device on which data readable by a computer system can be stored. Such computer-readable storage media may include non-volatile or non-transitory media such as ready-only memory (ROM), compact disc-ROM (CD-ROM), magnetic tape, floppy disks, memory cards, hard disks, magneto-optical disks, storage devices, and the like. Additionally, it may also include transitory media such as data transmission mediums. Furthermore, computer-readable storage media may be distributed across network-connected computer systems, with code stored and executed in a distributed manner.

Although operations are illustrated in the flowcharts/timing charts in this specification as being sequentially performed, this is merely an example description of the technical idea of one embodiment of the present disclosure. In other words, those having ordinary skill in the art to which one embodiment of the present disclosure belongs may appreciate that various modifications and changes can be made without departing from essential features of an embodiment of the present disclosure, i.e., the sequence illustrated in the flowcharts/timing charts can be changed and one or more operations of the operations can be performed in parallel. Thus, flowcharts/timing charts are not limited to the temporal order.

The above-described techniques, apparatuses, methods, and/or systems implementing such techniques, can further include battery management based at least in part upon the above techniques. For instance, apparatuses, and/or methods according to embodiments of the present disclosure may manage and/or control a battery based at least in part on the battery available area set using the above-described devices and/or methods. For example, such battery management may control charging the battery based on the SOC upper limit value set for the available area using the above-described apparatuses and/or methods and/or control discharging the battery based on the SOC lower limit value set for the available area using the above-described apparatuses and/or methods.

Although embodiments of the present disclosure have been described for illustrative purposes, those having ordinary skill in the art should appreciate that various modifications, additions, and substitutions are possible, without departing from the idea and scope of the claimed disclosure. Therefore, embodiments of the present disclosure have been described for the sake of brevity and clarity. The scope of the technical idea of the present disclosure is not limited by the illustrations. Accordingly, one of ordinary skill would understand that the scope of the claimed disclosure is not to be limited by the above explicitly described embodiments but by the claims and equivalents thereof.

What is claimed is:

1. A method comprising:
determining an estimated State of Charge (SOC);
determining an SOC at which a current starts to decrease by charging a battery at a constant voltage, as a reference SOC; and
predicting a State of Health (SOH) by comparing an absolute value of a difference between the estimated SOC and the reference SOC with a preset numerical value.

2. The method of claim 1, wherein predicting the SOH comprises:
predicting the SOH based on an SOH map and the reference SOC based on the absolute value of the difference between the estimated SOC and the reference SOC exceeding the preset numerical value.

3. The method of claim 1, further comprising:
setting an available area of the battery based on an SOH prediction result.

4. The method of claim 3, wherein setting the available area comprises:
setting the available area by setting an SOC lower limit value and an SOC upper limit value.

5. The method of claim 4, wherein setting the available area comprises:
setting the available area by fixing the SOC lower limit value and changing the SOC upper limit value.

6. The method of claim 5, wherein setting the available area comprises:
setting the available area by decreasing the SOC upper limit value as much as the SOH decreases.

7. The method of claim 1, wherein determining the estimated SOC comprises:
determining the estimated SOC by
integrating input and output currents of the battery, and
adding or subtracting an integration result to or from an initial capacity.

8. The method of claim 1, wherein determining the estimated SOC comprises:
determining the estimated SOC by measuring a voltage of the battery in a state where no load is connected to the battery.

9. The method of claim 1, wherein determining the estimated SOC comprises:
determining the estimated SOC by measuring a specific gravity of an electrolyte of the battery.

10. The method of claim 1, wherein determining the estimated SOC comprises:
determining the estimated SOC by measuring acidity (pH) of the battery.

11. The method of claim 1, wherein determining the estimated SOC comprises:
determining the estimated SOC by measuring an internal pressure of the battery.

12. An apparatus comprising:
at least one memory storing instructions; and
at least one processor,
wherein the at least one processor, by executing the instructions, is configured to:
determine an estimated State of Charge (SOC);
determine an SOC at which a current starts to decrease by charging a battery at a constant voltage, as a reference SOC; and
predict a State of Health (SOH) by comparing an absolute value of a difference between the estimated SOC and the reference SOC with a preset numerical value.

13. The apparatus of claim 12, wherein the at least one processor is configured to predict the SOH based on an SOH map and the reference SOC based on the absolute value of the difference between the estimated SOC and the reference SOC exceeding the preset numerical value.

14. The apparatus of claim 12, wherein the at least one processor is further configured to set an available area of the battery based on an SOH prediction result.

15. The apparatus of claim 14, wherein the at least one processor is configured to set the available area by setting a SOC lower limit value and a SOC upper limit value.

16. The apparatus of claim 15, wherein the at least one processor is configured to set the available area by fixing the SOC lower limit value and changing the SOC upper limit value.

17. The apparatus of claim 16, wherein the at least one processor is configured to set the available area by decreasing the SOC upper limit value as much as the SOH decreases.

18. The apparatus of claim 12, wherein the at least one processor is configured to determine the estimated SOC by:
integrating input and output currents of the battery, and
adding or subtracting an integration result to or from an initial capacity.

19. The apparatus of claim 12, wherein the at least one processor is configured to determine the estimated SOC by measuring a voltage of the battery in a state where no load is connected to the battery.

20. The apparatus of claim 12, wherein the at least one processor is configured to determine the estimated SOC by measuring a specific gravity of an electrolyte of the battery.
